(19) United States
(12) Patent Application Publication
(10) Pub. No.: US 2025/0191976 A1
(43) Pub. Date: Jun. 12, 2025

(54) METHOD OF MANUFACTURING CHIPS

(71) Applicant: DISCO CORPORATION, Tokyo (JP)

(72) Inventors: Norihisa ARIFUKU, Tokyo (JP); Masamitsu KIMURA, Tokyo (JP); Koshiro SUZUKI, Tokyo (JP)

(21) Appl. No.: 18/950,475

(22) Filed: Nov. 18, 2024

(30) Foreign Application Priority Data
Dec. 12, 2023 (JP) 2023-209271

(51) Int. Cl. H01L 21/78

(52) U.S. Cl. CPC H01L 21/78

(57) ABSTRACT

A method of manufacturing a plurality of chips from a workpiece by dividing the workpiece along a plurality of projected dicing lines established on a face side thereof includes a protective member forming step of forming a water-soluble protective member in covering relation to the face side, a cutting step of cutting the workpiece from the side of the protective member along the projected dicing lines with a cutting blade, and a protective member removing step of removing the protective member from the face side. The cutting step includes cutting the workpiece while supplying water at a first temperature or lower to the protective member to allow the protective member to remain on the face side, and the protective member removing step includes supplying water at a second temperature or higher that is higher than the first temperature to remove the protective member from the face side.

### BACKGROUND OF THE INVENTION

### Field of the Invention

The present invention relates to a method of manufacturing a plurality of chips from a workpiece by dividing the workpiece.

### Description of the Related Art

Device chips, which are also simply referred to as chips, having such devices as electronic circuits, for example, are indispensable elements in various electronic appliances, typically, cellular phones and personal computers. Such device chips are fabricated from a wafer made of such a material as silicon (Si) by demarcating a plurality of areas on a face side of the wafer with a grid of straight projected dicing lines, constructing devices in the respective demarcated areas, and dividing the wafer along the projected dicing lines into pieces as device chips.

For dividing a plate-shaped workpiece typified by a wafer into a plurality of device chips along projected dicing lines established on the wafer, there may be used a cutting apparatus having a machining tool called a cutting blade mounted on a spindle (see, for example, JP 2001-144034A). In operation, the cutting apparatus rotates the cutting blade at a high speed and causes it to cut into the workpiece along the projected dicing lines while supplying liquid such as water to the cutting blade and the workpiece.

Some workpieces such as wafers have devices each including an insulating film that has a low dielectric constant, referred to as a low-k film. When the cutting blade that is rotating at a high speed cuts into such a workpiece, the low-k film may be peeled off over a wide zone, possibly damaging some of the devices. The problem may be solved by covering the surface of the workpiece where the low-k film is present with a protective member such as a resin film and then causing the cutting blade to cut into the workpiece.

### SUMMARY OF THE INVENTION

The protective member used in the manner described above needs to remain on the surface of the workpiece until the cutting blade finishes cutting the workpiece, in order to protect the surface of the workpiece properly. Therefore, the protective member is made of a material that is hardly dissolvable in the water applied when the cutting blade cuts the workpiece. After the workpiece has been cut by the cutting blade, a chemical such as an acid, an alkali, or an organic solvent is applied to remove the protective member from the workpiece. However, the process of handling the chemical is troublesome as it involves safely keeping the chemical in storage, carefully applying the chemical to the workpiece, and properly processing a discharged waste liquid containing the used chemical.

It is therefore an object of the present invention to provide a method of manufacturing chips from a workpiece while minimizing the troublesome handling of a chemical that is required to remove a protective member from the workpiece after the workpiece has been processed.

In accordance with an aspect of the present invention, there is provided a method of manufacturing a plurality of chips from a workpiece by dividing the workpiece along a plurality of projected dicing lines established on a face side thereof, including a protective member forming step of forming a water-soluble protective member in covering relation to the face side of the workpiece, after the protective member forming step, a cutting step of cutting the workpiece from a side of the protective member along the projected dicing lines with a cutting blade, and after the cutting step, a protective member removing step of removing the protective member from the face side of the workpiece, in which the cutting step includes cutting the workpiece while supplying water at a first temperature or lower to the protective member to allow the protective member to remain on the face side of the workpiece, and the protective member removing step includes supplying water at a second temperature or higher that is higher than the first temperature to remove the protective member from the face side of the workpiece.

The protective member forming step may include forming the protective member in intimate contact with the face side of the workpiece by heating a member that is produced by forming a water-soluble thermoplastic resin into a film to soften or melt the member and pressing the softened or melted member against the workpiece.

The protective member forming step may include forming the protective member by using a water-soluble resin having a property of dissolvable and removable in a period of time ranging from 7 to 125 seconds per thickness of 1 μm when formed into a film having a thickness ranging from 10 to 80 μm and water at the first temperature is supplied to the film, and a property of dissolvable and removable in a period of time ranging from 0.1 to 1.0 seconds per thickness of 1 μm when formed into a film having a thickness ranging from 10 to 80 μm and water at the second temperature is supplied to the film.

The protective member forming step may include forming the protective member by using polyvinyl alcohol whose saponification degree is 96 mol % or higher.

The first temperature is 25° C., and the second temperature is 50° C., for example.

In the above method of manufacturing a plurality of chips according to the aspect of the present invention, the water-soluble protective member is formed in covering relation to the face side of the workpiece in the protective member forming step, the water at the first temperature or lower is supplied to the protective member in the cutting step, and the water at the second temperature or higher that is higher than the first temperature is supplied to the protective member in the protective member removing step.

Therefore, in the cutting step, the workpiece is cut while the protective member remains unremoved on the workpiece by the water supplied at the first temperature or lower. On the other hand, in the protective member removing step, the protective member is removed from the workpiece by the water supplied at the second temperature or higher. Inasmuch as no chemical needs to be used to remove the protective member, no troublesome chemical handling process is involved in removing the protective member from the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating the appearance of a workpiece;

FIG. 2 is a side elevational view schematically illustrating the manner in which a resin film that is to become a protective member subsequently is brought into intimate contact with the workpiece;

FIG. 3 is a side elevational view schematically illustrating the manner in which the resin film is cut into the protective member;

FIG. 4 is a side elevational view, partly in cross section, schematically illustrating the manner in which the workpiece is cut; and

FIG. 5 is a side elevational view, partly in cross section, schematically illustrating the manner in which the protective member is removed from the workpiece.

### DETAILED DESCRIPTION OF THE PREFERRED EMBODIMENT

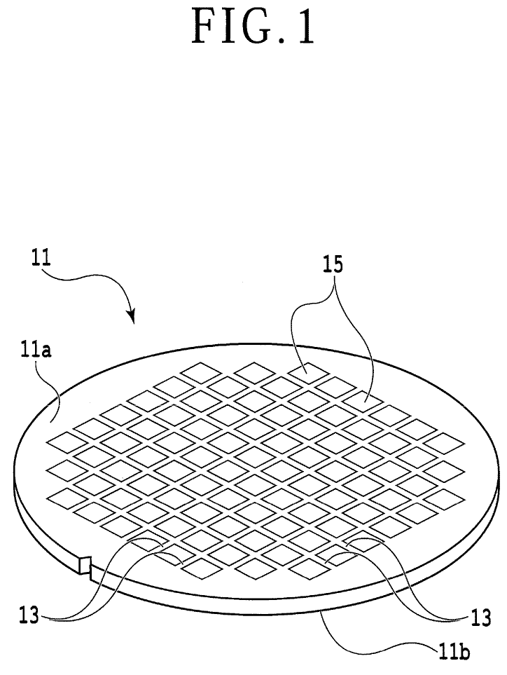

A method of manufacturing a plurality of chips from a workpiece, also referred to as a “chip manufacturing method,” according to a preferred embodiment of the present invention will be described below with reference to the accompanying drawings. FIG. 1 illustrates in perspective the appearance of a workpiece 11 to be processed in the chip manufacturing method. As illustrated in FIG. 1, the workpiece 11 is a disk-shaped wafer made of a semiconductor material such as Si, for example. The workpiece 11 has a circular face side (first surface) 11a depicted as facing upwardly and a circular reverse side (second surface) 11b depicted as facing downwardly, opposite the face side 11a.

The workpiece 11 includes an unillustrated functional layer on the face side 11a thereof. The functional layer is made up of one or more films including, for example, a metal film that provides interconnects, an insulating film that provides insulation between the interconnects and that may include a low-k film, and a semiconductor film. The low-k film that may be included in the functional layer typically includes an inorganic insulating film made of an inorganic material such as fluorine-doped silicon oxide (SiOF) or boron-doped silicon oxide (SiOB) or an organic insulating film made of a polyimide-base polymer or a parylene-base polymer.

The face side 11a of the workpiece 11 has a plurality of small areas demarcated by a grid of straight projected dicing lines or streets 13 each having a predetermined width. The areas include respective devices 15 such as integrated circuits (ICs) constructed therein that include components provided by the functional layer. The function layer including the insulating film has portions present in the projected dicing lines 13.

According to the present embodiment, the workpiece 11 is a disk-shaped wafer made of a semiconductor material such as Si, for example, as described above. According to the present invention, however, the workpiece 11 is not limited to any particular material, shape, structure, and size. The workpiece 11 may be a substrate made of another semiconductor material, ceramic, resin, or metal. Similarly, the devices 15 are not limited to any particular kind, quantity, shape, structure, size, and layout. The workpiece 11 may even be free of the devices 15.

In the chip manufacturing method according to the present embodiment, the workpiece 11 is divided along the projected dicing lines 13 into a plurality of chips that include the respective devices 15. Specifically, the workpiece 11 is severed along the projected dicing lines 13 by a machining tool referred to as a cutting blade.

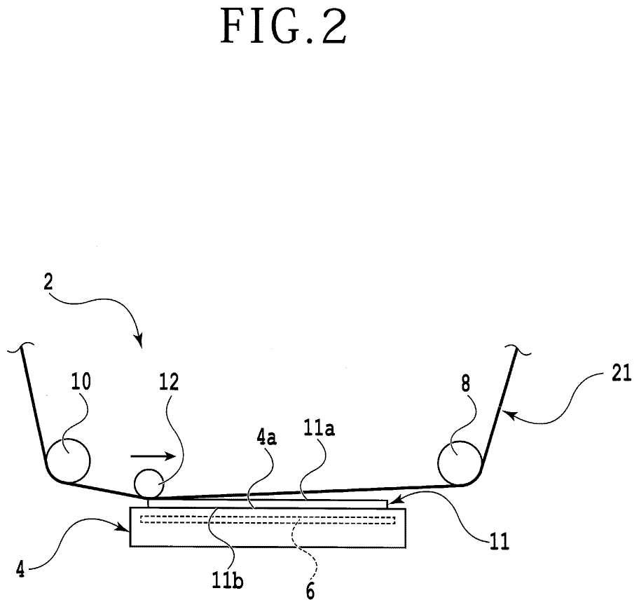

In the chip manufacturing method, first, a water-soluble protective member for protecting the face side 11a of the workpiece 11 from the cutting blade is formed in covering relation to the face side 11a (protective member forming step). According to the present embodiment, a resin film is brought into intimate contact with the face side 11a by way of thermocompression bonding to form the protective member. FIG. 2 schematically illustrates in side elevation the manner in which a resin film 21 that is to become a protective member subsequently is brought into intimate contact with the workpiece 11.

The resin film 21 is produced by forming a water-soluble thermoplastic resin into a film having a desired thickness, preferably, a thickness in the range of 10 to 80 μm. The ease with which the water-soluble thermoplastic resin is dissolvable in water greatly varies depending on the temperature. The water-soluble thermoplastic resin may include polyvinyl alcohol (PVA) having a high saponification degree. As the saponification degree of PVA increases, PVA is less dissolvable in low-temperature water.

The saponification degree of PVA should preferably be 97% or higher in a case where the degree of polymerization of PVA is in the range of 600 to 1700 exclusive, and should preferably be 96% or higher in a case where the degree of polymerization of PVA is 1700 or higher.

For example, when water at a temperature of 25° C. is supplied to the resin film 21 that is made of PVA with such a saponification degree and has a thickness of 40 μm, the resin film 21 is dissolved in a period of time ranging from 280 to 5000 seconds and removed. Stated otherwise, the water-soluble resin that the resin film 21 is made of is dissolved in a period of time ranging from 7 to 125 seconds per thickness of 1 μm and removed when water at a temperature of 25° C. is supplied to the resin film 21. Therefore, if the period of time that is spent until the severance of the workpiece 11 is completed is 280 seconds or less, then the resin film 21 functions properly as a protective member for protecting the face side 11a of the workpiece 11 by adjusting the temperature of water applied while cutting the workpiece 11 to 25° C. or lower.

When water at a temperature of 50° C. is supplied to the resin film 21 that is made of PVA with such a saponification degree and has a thickness of 40 μm, the resin film 21 is dissolved in a period of time ranging from 4 to 40 seconds and removed. Stated otherwise, the water-soluble resin that the resin film 21 is made of is dissolved in a period of time ranging from 0.1 to 1.0 second per thickness of 1 μm and removed when water at a temperature of 50° C. is supplied to the resin film 21. Therefore, if the period of time that is allowed to remove the protective member is 40 seconds or more, then the resin film 21 can appropriately be removed without the use of a chemical when water adjusted to a temperature of 50° C. or higher is supplied. As described above, the PVA that satisfies the above conditions is suitable for use as the material of the resin film 21 that is to become the protective member.

The PVA that is used as the material of the resin film 21 may contain other monomeric units as long as they do not cause the PVA to lose the above features. The monomeric units that may be contained in the PVA include α-olefins such as ethylene, propylene, 1-butene, isobutene, and 1-hexsene, acrylic esters such as acrylic acid and its salt and methyl acrylate, ethyl acrylate, n-propyl acrylate, i-propyl acrylate, n-butyl acrylate, i-butyl acrylate, t-butyl acrylate, 2-ethylhexyl acrylate, dodecyl acrylate, and octadecyl acrylate, methacrylate esters such as methacrylic acid and its salt, methyl methacrylate, ethyl methacrylate, n-propyl methacrylate, i-propyl methacrylate, n-butyl methacrylate, i-butyl methacrylate, t-butyl methacrylate, 2-ethylhexyl methacrylate, dodecyl methacrylate, and octadecyl methacrylate, acrylamide derivatives such as acrylamide, N-methyl acrylamide, N-ethyl acrylamide, N, N-dimethyl acrylamide, diacetone acrylamide, acrylamide propanesulfonic acid and its salt, acrylamide propyl dimethylamine and its salt, and N-methylol acrylamide and its derivatives, methacrylamide derivatives such as methacrylamide, N-methyl methacrylamide, N-ethyl methacrylamide, methacrylamide propanesulfonic acid and its salt, methacrylamide propyl dimethylamine and its salt, and N-methylol methacrylamide and its derivatives, N-vinyl amides such as N-vinyl pyrrolidone, N-vinyl formamide, and N-vinyl acetamide, aryl ethers having polyalkylene oxide in its side chain, vinyl ethers such as methyl vinyl ether, ethyl vinyl ether, n-propyl vinyl ether, i-propyl vinyl ether, n-butyl vinyl ether, i-butyl vinyl ether, t-butyl vinyl ether, dodecyl vinyl ether, and stearyl vinyl ether, nitriles such as acrylonitrile and methacrylonitrile, vinyl halides such as vinyl chloride, vinylidene chloride, vinyl fluoride, and vinylidene fluoride, allyl compounds such as allyl acetate and allyl chloride, vinylsilyl compounds such as maleic acid and its salt or its ester and vinyl trimethoxysilane, and isopropenyl acetate, for example.

A plasticizer may be added to the water-soluble thermoplastic resin that the resin film 21 is made of. In other words, the water-soluble thermoplastic resin that the resin film 21 is made of may contain a plasticizer in addition to the PVA described above. The plasticizer that may be added to the resin film 21 allows the resin film 21 to be deformed easily to follow the configuration of the face side 11a of the workpiece 11, and hence to be kept reliably in intimate contact with the workpiece 11.

The plasticizer may be any of materials that are generally used as PVA plasticizers. Specifically, the plasticizers may include, for example, polyalcohols such as glycerin, diglycerin, diethylene glycol, triethylene glycol, propylene glycol, dipropylene glycol, trimethylol propane, pentaerythritol, and 1,3-butanediol, polyethers such as polyethylene glycol and polypropylene glycol, polyvinyl amides such as polyvinyl pyrrolidone, amide compounds such as N-methyl pyrrolidone and dimethyl acetamide, compounds in which ethylene oxide is added to polyalcohols such as glycerin, pentaerythritol, and sorbitol, or water, for example. Only one or two or more of the above plasticizers may be added to the resin film 21.

Any of these plasticizers may be added to the resin film 21 for the purpose of making the resin film 21 more water-soluble in addition to the purpose of increasing the ability of the resin film 21 to follow the configuration of the workpiece 11. For making the resin film 21 more water-soluble, it is preferable to use glycerin, diglycerin, diethylene glycol, triethylene glycol, propylene glycol, dipropylene glycol, trimethylol propane, polyethylene glycol, or polypropylene glycol as the plasticizer. In order to prevent the resin film 21 from becoming less water-soluble due to bleeding-out of the plasticizer, it is particularly preferable to use glycerin, diglycerin, trimethylol propane, polyethylene glycol, or polyvinyl pyrrolidone as the plasticizer.

The period of time during which the resin film 21 is to keep itself undissolved and the period of time allowed until the resin film 21 is dissolved and removed vary depending on the period of time required until the severance of the workpiece 11 is completed and the period of time allowed to clean the workpiece 11. Therefore, the thickness of the workpiece 11 may be changed as desired depending on these conditions, i.e., these periods of time.

For bringing the resin film 21 into intimate contact with the workpiece 11, a protective member forming apparatus 2 illustrated in FIG. 2 is used. The protective member forming apparatus 2 includes a support table 4 capable of supporting the workpiece 11 from below, i.e., supporting the workpiece 11 on an upper surface 4a thereof. The support table 4 houses therein a heater 6 for heating the workpiece 11 placed on the upper surface 4a.

The protective member forming apparatus 2 also includes, above the support table 4, an unillustrated support roller for supporting thereon a roll of the resin film 21 and an unillustrated take-up roller for winding thereon the resin film 21 that has been reeled out as a resin film strip from the support roller. The protective member forming apparatus 2 further includes a pair of guide rollers 8 and 10 disposed downstream of the support roller and upstream of the take-up roller with respect to the direction in which the resin film 21 is reeled out from the support roller toward the take-up roller. The guide rollers 8 and 10 for guiding the resin film 21 that has been reeled out of the support roller into a space above the support table 4 are horizontally spaced from each other across the space above the support table 4.

Disposed between the guide rollers 8 and 10 is a presser roller 12 for applying a downward pressure to the resin film 21 that has been guided into the space above the support table 4. The presser roller 12 is supported on an unillustrated roller moving mechanism including a ball screw, for example. When the roller moving mechanism is actuated, it moves the presser roller 12 in horizontal directions substantially parallel to the upper surface 4a of the support table 4 and vertical directions substantially perpendicular to the upper surface 4a of the support table 4.

For bringing the resin film 21 into intimate contact with the workpiece 11 with use of the protective member forming apparatus 2, first, the workpiece 11 is placed on the support table 4 such that the reverse side 11b of the workpiece 11 is held in contact with the upper surface 4a of the support table 4. The workpiece 11 is now supported on the support table 4 with the face side 11a facing upwardly.

When the workpiece 11 has been supported on the support table 4, the heater 6 is energized to generate and apply heat to the workpiece 11. The resin film 21 reeled out as a resin film strip from the support roller is guided by the guide rollers 8 and 10 into the space above the support table 4 and hence the workpiece 11. Thereafter, the roller moving mechanism is actuated to lower the presser roller 12 between the guide rollers 8 and 10 toward the workpiece 11.

The presser roller 12 is further lowered into contact with the resin film 21 above the workpiece 11. Continued descent of the presser roller 12 lowers a portion of the resin film 21 contacted thereby into contact with the face side 11a of the workpiece 11 under the downward pressure imposed by the presser roller 12. Since the workpiece 11 has been heated by the heat generated by the heater 6, the portion of the resin film 21 that has been held in contact with the face side 11a of the workpiece 11 is softened or melted by the heat from the workpiece 11.

The softened or melted portion of the resin film 21 is pressed against the face side 11a of the workpiece 11 by the pressure from the presser roller 12. Thereafter, as illustrated in FIG. 2, while the presser roller 12 is having its height maintained over the support table 4, the roller moving mechanism moves the presser roller 12 in a horizontal direction indicated by the arrow substantially parallel to the upper surface 4a of the support table 4. The presser roller 12 now presses the resin film 21 against the face side 11a of the workpiece 11 in its entirety by way of thermocompression bonding, holding the resin film 21 in intimate contact with the workpiece 11.

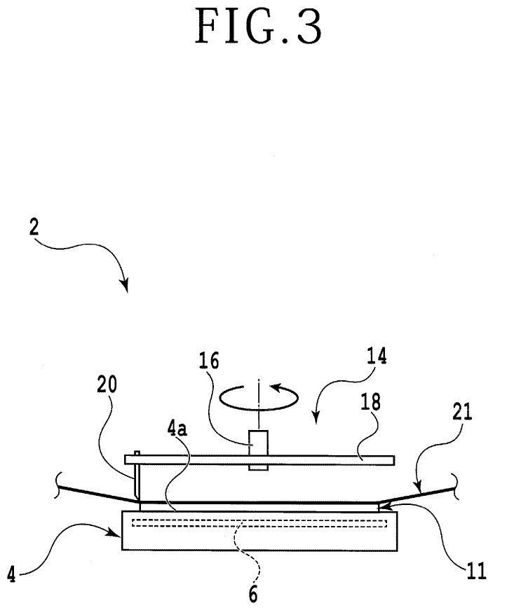

After the resin film 21 has been held in intimate contact with the workpiece 11 by way of thermocompression bonding, the resin film 21 is cut into a circular shape corresponding to the workpiece 11, thereby forming a protective member on the workpiece 11. FIG. 3 schematically illustrates in side elevation the manner in which the resin film 21 is cut into the protective member. The resin film 21 is cut into the protective member with use of the protective member forming apparatus 2.

As illustrated in FIG. 3, the protective member forming apparatus 2 has a film cutting unit 14 disposed above the support table 4 out of physical interference with the guide rollers 8 and 10 and the presser roller 12. The film cutting unit 14 includes a rod-shaped spindle 16 that is elongate vertically and extends perpendicularly to the upper surface 4a of the support table 4.

The spindle 16 is supported on an unillustrated vertically moving mechanism including a ball screw. When the vertically moving mechanism is actuated, it moves the spindle 16 in directions perpendicular to the upper surface 4a of the support table 4. The spindle 16 has an upper proximal end connected to a rotary actuator such as an electric motor. When the rotary actuator is energized, it rotates the spindle 16 about its vertical central axis extending therethrough perpendicularly to the upper surface 4a of the support table 4.

The spindle 16 has a lower distal end fixed to a central portion of a horizontal support member 18 having a predetermined length perpendicular to the vertical central axis of the spindle 16. For example, the support member 18 is of a disk shape slightly larger in diameter than the workpiece 11. The predetermined length of the support member 18 is represented by the diameter of the support member 18. A cutter 20 capable of severing the resin film 21 is mounted on a circumferential edge portion of the support member 18. The cutter 20 mounted on the support member 18 has a lower cutting edge directed downwardly. The distance from the vertical central axis of the spindle 16 to the cutter 20 mounted on the support member 18 is approximately the same as the radius of the workpiece 11.

For severing the resin film 21 into a shape corresponding to the workpiece 11, first, the position of the spindle 16 in a direction generally perpendicular to the upper surface 4a of the support table 4 is adjusted by the vertically moving mechanism so as to cause the lower cutting edge of the cutter 20 to cut into the resin film 21. Then, the rotary actuator rotates the spindle 16 about its vertical central axis.

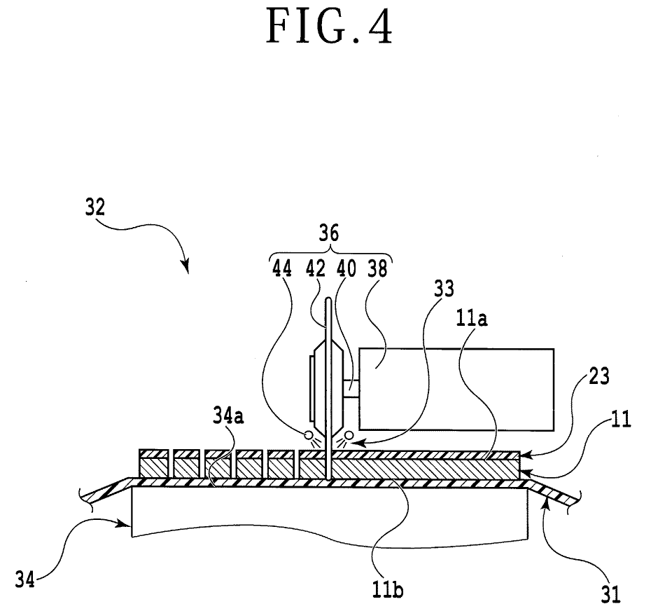

The cutter 20 now moves along the circumferential edge of the workpiece 11, severing the resin film 21 into a circular shape corresponding to the workpiece 11, i.e., a protective member. The position of the spindle 16 may be adjusted so as to cause the lower cutting edge of the cutter 20 to cut into the resin film 21 while the spindle 16 is rotating about its vertical central axis. In this manner, a circular water-soluble protective member 23 (see FIG. 4) that covers the face side 11a of the workpiece 11 is cut out of the resin film 21.

After the protective member 23 has been formed from the resin film 21, the workpiece 11 is cut from the side of the protective member 23 along the projected dicing lines 13, so that the workpiece 11 is divided into a plurality of chips (cutting step). FIG. 4 schematically illustrates in side elevation, partly in cross section, the manner in which the workpiece 11 is cut. According to the present embodiment, before the workpiece 11 starts to be cut, a tape 31 is affixed to the reverse side 11b of the workpiece 11, and an unillustrated annular frame is fixed to a peripheral edge portion of the tape 31 in surrounding relation to the workpiece 11. The tape 31 and the annular frame thus combined with the workpiece 11 allows the workpiece 11 to be handled with increase ease.

For cutting the workpiece 11, a cutting apparatus 32 illustrated in FIG. 4, for example, is used. The cutting apparatus 32 includes a disk-shaped chuck table 34 for holding thereon the workpiece 11 supported on the annular frame by the tape 31. The chuck table 34 has an upper surface 34a. A portion of the upper surface 34a of the chuck table 34 functions as a holding surface for holding the workpiece 11 under suction thereon. The portion of the upper surface 34a as the holding surface is typically made of porous ceramic.

The portion of the upper surface 34a as the holding surface is fluidly connected to a suction source such as an ejector, for example, via an unillustrated fluid channel defined in the chuck table 34 and an unillustrated valve fluidly connected to the fluid channel and disposed outside of the chuck table 34. A plurality of, e.g., four, unillustrated clamps for gripping the annular frame to secure the workpiece 11 on the holding surface are disposed around the chuck table 34.

The chuck table 34 has a lower portion coupled to an unillustrated rotary actuator such as an electric motor. When the rotary actuator is energized, it rotates the chuck table 34 about its vertical central axis that extends through the center of the upper surface 34a of the chuck table 34 substantially perpendicularly to the upper surface 34a. The chuck table 34 is supported on an unillustrated table moving mechanism. When the table moving mechanism is actuated, it moves the chuck table 34 along a first direction, i.e., a processing feed direction, substantially parallel to the upper surface 34a of the chuck table 34.

The cutting apparatus 32 further includes a cutting unit 36 disposed above the chuck table 34. The cutting unit 36 includes a tubular spindle housing 38 in which a portion of a rod-shaped spindle 40 is rotatably housed. The spindle 40 extends horizontally in a second direction, i.e., an indexing feed direction, that is substantially perpendicular to the first direction referred to above and substantially parallel to the upper surface 34a of the chuck table 34.

The spindle 40 has an end portion that is exposed out of the spindle housing 38 and that supports thereon an annular cutting blade 42 lying vertically perpendicularly to the upper surface 34a of the chuck table 34. The cutting blade 42 is made of abrasive grains of diamond, for example, dispersed in a binder of resin, for example. The spindle 40 has an opposite end portion coupled to an unillustrated rotary actuator such as an electric motor. When the rotary actuator is energized, it rotates the spindle 40 about its horizontal central axis that extends substantially parallel to the second direction.

A pair of nozzles 44 for ejecting water, i.e., a cutting fluid, 33 toward the workpiece 11 and the cutting blade 42 are disposed one on each side of the cutting blade 42 and spaced from the cutting blade 42 along the second direction. The nozzles 44 have respective ejection ports oriented toward the machining point where the cutting blade 42 will contact the workpiece 11. When the cutting blade 42 is caused to cut into the workpiece 11, the ejection ports of the nozzles 44 eject water 35 toward the machining point.

For cutting the workpiece 11 on the cutting apparatus 32 thus arranged, the reverse side 11b of the workpiece 11 is held on the chuck table 34. Specifically, the workpiece 11 is placed on the chuck table 34 such that the tape 31 affixed to the workpiece 11 is held against the upper surface 34a of the chuck table 34.

Then, the valve that is fluidly connected to the fluid channel defined in the chuck table 34 is opened to allow a negative pressure generated by the suction source to act from the upper surface 34a of the chuck table 34 on the tape 31. The tape 31 is now attracted under suction to the chuck table 34, causing the workpiece 11 to be held on the chuck table 34 through the tape 31 interposed therebetween. The annular frame fixed to the peripheral edge portion of the tape 31 is gripped by the four clamps around the chuck table 34.

Then, the workpiece 11 is cut by the cutting blade 42. Specifically, the rotary actuator coupled to the chuck table 34 is energized to adjust the orientation of the chuck table 34 in order to direct a target one of the projected dicing lines 13, along which the workpiece 11 is to be cut, along the first direction. The table moving mechanism adjusts the position of the chuck table 34 along the first direction, and the cutting unit moving mechanism adjusts the position of the cutting unit 36 along the second direction, so that the cutting blade 42 is positioned above an extension of the target projected dicing line 13.

Then, the cutting unit moving mechanism adjusts the vertical position of the cutting unit 36 to make the position, i.e., height, of the lower end of the cutting blade 42 slightly lower than the upper surface of the tape 31 affixed to the workpiece 11. Thereafter, while the cutting blade 42 is being rotated by the spindle 40, the table moving mechanism moves the chuck table 34 along the first direction. The rotating cutting blade 42 cuts into the workpiece 11 along the target projected dicing line 13, severing the workpiece 11 along the target projected dicing line 13.

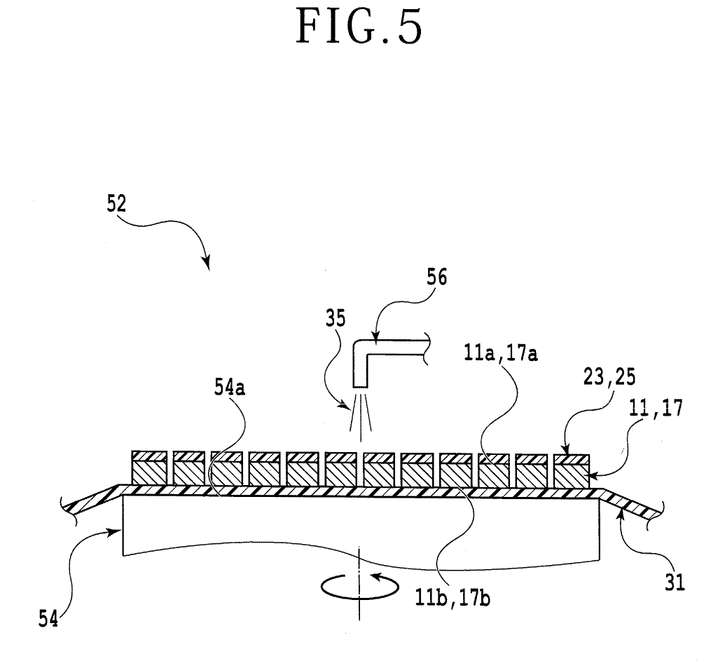

After the workpiece 11 has been severed along the target projected dicing line 13, the workpiece 11 is similarly cut along a next target projected dicing line 13 by the cutting blade 42, so that the workpiece 11 is severed along the next target projected dicing line 13. In this manner, the workpiece 11 is repeatedly severed along all the projected dicing lines 13 until the workpiece 11 is divided into a plurality of chips 17 (see FIG. 5).

While the cutting blade 42 is cutting into the workpiece 11, the nozzle 44 continuously supplies the water 35 to the machining point. If the period of time spent until the cutting of the workpiece 11 along all the projected dicing lines 13 is finished is 280 seconds, then the protective member 23 needs to remain undissolved on the face side 11a of the workpiece 11 during at least these 280 seconds. According to the present embodiment, in order to fulfil this requirement, the water 35 that is kept at a first temperature or lower is supplied to the machining point where the protective member 23 is also present.

In a case where the protective member 23 that is 40 μm thick is made of the PVA that meets the above requirement, the first temperature that represents an upper limit for a range of temperatures suitable for the water 33 is set to 25° C. Therefore, until the cutting of the workpiece 11 is finished, the protective member 23 remains undissolved on the face side 11a of the workpiece 11, protecting the face side 11a of the workpiece 11.

There is no particular lower limit for the range of temperatures suitable for the water 33 supplied to the machining point at the time when the workpiece 11 is cut by the cutting blade 42. The temperature of the water 33 may be varied in a range of 5° C. to 25° C., for example, depending on the period of time required until the cutting of the workpiece 11 along all the projected dicing lines 13 is finished. The rate at which the water 33 is supplied from the nozzles 44 ranges from 0.5 to 3.0 L/min, but is typically approximately 1.5 L/min. However, the rate at which the water 33 is supplied from the nozzles 44 may be varied in a range of rates established for appropriately cutting the workpiece 11 with the cutting blade 42.

After the workpiece 11 has been divided into the chips 17, protected member fragments 25 produced by cutting the workpiece 11 and the protective member 23 are removed from respective face sides (first surfaces) 17a of the chips 17 that correspond to the face side 11a of the workpiece 11 (protective member removing step). FIG. 5 schematically illustrates in side elevation, partly in cross section, the manner in which the protective member 23, i.e., the protective member fragments 25, is removed from the workpiece 11, i.e., the chips 17.

For removing the protective member fragments 25 from the respective chips 17, a cleaning apparatus 52 illustrated in FIG. 5 is used, for example. The cleaning apparatus 52 includes a disk-shaped spinner table 54 for holding thereon the chips 17 cut from the workpiece 11 that are supported on the frame by the tape 31. The spinner table 54 has an upper surface 54a with unillustrated suction ports defined therein. The upper surface 54a has a portion functioning as a holding surface for holding the chips 17 under suction thereon through the tape 31 interposed therebetween.

The suction ports defined in the upper surface 54a of the spinner table 54 are fluidly connected to a suction source such as an ejector, for example, via an unillustrated fluid channel defined in the spinner table 54 and an unillustrated valve fluidly connected to the fluid channel and disposed outside of the spinner table 54. The spinner table 54 has a lower portion coupled to an unillustrated rotary actuator such as an electric motor. When the rotary actuator is energized, it rotates the spinner table 54 about its vertical central axis that extends through the center of the upper surface 54a of the spinner table 54 substantially perpendicularly to the upper surface 54a.

A plurality of, e.g., four, unillustrated clamps for gripping the annular frame to secure the workpiece 11 on the holding surface are disposed around the spinner table 54. The cleaning apparatus 52 further includes a nozzle 56 that is disposed above the spinner table 54 and that is for ejecting cleaning water, i.e., a cleaning fluid, 35 downwardly from an ejection port defined in a lower distal end of the nozzle 56. The nozzle 56 has an upper proximal end coupled to a rotary actuator such as an electric motor. When the rotary actuator is energized, it turns the lower distal end of the nozzle 56 back and forth along an arcuate track substantially parallel to the upper surface 54a of the spinner table 54.

For removing the protective member fragments 25 from the respective chips 17 on the cleaning apparatus 52, first, respective reverse sides (second surfaces) 17b of the chips 17 are placed on the spinner table 54 through the tape 31 interposed therebetween. Specifically, the chips 17 are placed on the spinner table 54 such that the tape 31 affixed to the reverse sides 17b of the chips 17 is held against the upper surface 54a of the spinner table 54.

Then, the valve that is fluidly connected to the fluid channel defined in the spinner table 54 is opened to allow a negative pressure generated by the suction source to act from the upper surface 54a of the spinner table 54 on the tape 31. The tape 31 is now attracted under suction to the spinner table 54, causing the workpiece 11 to be held on the spinner table 54 through the tape 31 interposed therebetween. Then, the rotary actuator rotates the spinner table 54 about its vertical central axis. During the rotation of the spinner table 54, the annular frame fixed to the peripheral edge portion of the tape 31 is gripped by the four clamps around the chuck table 34.

Thereafter, the ejection port of the nozzle 56 ejects the water 35 toward the chips 17 below the nozzle 56. At the same time that the ejection port of the nozzle 56 ejects the water 35 toward the chips 17, the lower distal end of the nozzle 56 with the ejection port defined therein swings or turns back and forth over the spinner table 54 in the arcuate track substantially parallel to the upper surface 54a of the spinner table 54, spreading the water 35 over the protective member fragments 25. The water 35 ejected from the ejection port of the nozzle 56 is applied to the protective member fragments 25, dissolving the protective member fragments 25. In this manner, the protective member fragments 25, i.e., the protective member 23, are removed from the face side 11a of the workpiece 11.

If the period of time allowed for removing the protective member 23, i.e., all the protective member fragments 25, covering the workpiece 11 is 40 seconds, for example, then it is necessary for the protective member 23 to be dissolved in the water 35 and removed from the face side 11a of the workpiece 11 within the period of time. According to the present embodiment, in order to fulfil this requirement, the water 35 that is kept at a second temperature or higher is supplied to the protective member fragments 25, i.e., the protective member 23.

In a case where the protective member 23 that is 40 μm thick is made of the PVA that meets the above requirement, the second temperature that represents a lower limit for a range of temperatures suitable for the water 35 is set to 50° C. Therefore, the protective member 23 is appropriately removed from the face side 11a of the workpiece 11 within a short period of time. In addition, there is no need for a chemical to be used for removing the protective member 23.

There is no particular upper limit for the range of temperatures suitable for the water 35 supplied to remove the protective member 23, i.e., all the protective member fragments 25, covering the workpiece 11. The temperature of the water 35 may be varied in a range of 50° C. to 80° C., for example, depending on the period of time allowed for removing the protective member 23, i.e., all the protective member fragments 25. The rate at which the water 35 is supplied from the nozzle 56 ranges from 0.1 to 1.0 L/min, but is typically approximately 0.2 L/min. However, the rate at which the water 35 is supplied from the nozzle 56 may be varied in a range of rates established for appropriately removing the protective member 23. Moreover, the water 35 may be ejected as being mixed with gas such as air from the nozzle 56.

In the chip manufacturing method according to the present embodiment, as described above, first, the water-soluble protective member 23 is formed in covering relation to the face side 11a of the workpiece 11 (protective member forming step). Then, when the workpiece 11 is cut, the water 33 at the first temperature or lower is supplied to the protective member 23 (cutting step). Thereafter, for removing the protective member 23, the water 35 at the second temperature or higher that is higher than the first temperature is supplied to the protective member 23 (protective member removing step).

Therefore, while the workpiece 11 is being cut, the protective member 23 remains undissolved in the water 33 that is held at the first temperature or lower. For removing the protective member 23, the water 35 at the second temperature or higher is applied to the protective member 23, which is dissolved in the water 35 and removed from the workpiece 11. Inasmuch as no chemical needs to be used to remove the protective member 23, no troublesome chemical handling process is involved in removing the protective member 23 from the workpiece 11.

Various changes and modifications may be made in the embodiment described above. According to the above embodiment, the workpiece 11 is cut into the chips 17 by the cutting blade 42. However, after the face side 11a of the workpiece 11 has been cut by the cutting blade 42, the workpiece 11 may be divided into the chips 17 according to other processes than using the cutting blade 42.

Specifically, for example, the cutting blade 42 may be caused to cut into the workpiece 11 to a depth short of fully severing the workpiece 11, thereby forming slots in the workpiece 11 that are open at the face side 11a thereof (cutting step). Thereafter, the workpiece 11 is ground in its entirety from the reverse side 11b thereof to a thickness smaller than the depth of the slots, dividing the workpiece 11 into the chips 17 (grinding step). If the workpiece 11 is not fully severed by the cutting blade 42 as described above, then the tape 31 and the annular frame may not necessarily be used in combination with the workpiece 11.

According to the above embodiment, the resin film 21 that is produced by forming a water-soluble thermoplastic resin into a film is softened or melted by heat and pressed against and brought into intimated contact with the face side 11a of the workpiece 11 by way of thermocompression bonding. However, the protective member 23 may be formed by other processes such as a spin-coating process.

The structural and methodical details of the above embodiment may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing a plurality of chips from a workpiece by dividing the workpiece along a plurality of projected dicing lines established on a face side thereof, comprising:
a protective member forming step of forming a water-soluble protective member in covering relation to the face side of the workpiece;
after the protective member forming step, a cutting step of cutting the workpiece from a side of the protective member along the projected dicing lines with a cutting blade; and
after the cutting step, a protective member removing step of removing the protective member from the face side of the workpiece,
wherein the cutting step includes cutting the workpiece while supplying water at a first temperature or lower to the protective member to allow the protective member to remain on the face side of the workpiece, and
the protective member removing step includes supplying water at a second temperature or higher that is higher than the first temperature to remove the protective member from the face side of the workpiece.

2. The method of manufacturing a plurality of chips according to claim 1, wherein the protective member forming step includes forming the protective member in intimate contact with the face side of the workpiece by heating a member that is produced by forming a water-soluble thermoplastic resin into a film to soften or melt the member and pressing the softened or melted member against the workpiece.

3. The method of manufacturing a plurality of chips according to claim 1, wherein the protective member forming step includes forming the protective member by using a water-soluble resin having a property of dissolvable and removable in a period of time ranging from 7 to 125 seconds per thickness of 1 μm when formed into a film having a thickness ranging from 10 to 80 μm and water at the first temperature is supplied to the film, and a property of dissolvable and removable in a period of time ranging from 0.1 to 1.0 seconds per thickness of 1 μm when formed into a film having a thickness ranging from 10 to 80 μm and water at the second temperature is supplied to the film.

4. The method of manufacturing a plurality of chips according to claim 1, wherein the protective member forming step includes forming the protective member by using polyvinyl alcohol whose saponification degree is 96 mol % or higher.

5. The method of manufacturing a plurality of chips according to claim 1, wherein the first temperature is 25° C., and the second temperature is 50° C.

6. The method of manufacturing a plurality of chips according to claim 2, wherein the protective member forming step includes forming the protective member by using a water-soluble resin having a property of dissolvable and removable in a period of time ranging from 7 to 125 seconds per thickness of 1 μm when formed into a film having a thickness ranging from 10 to 80 μm and water at the first temperature is supplied to the film, and a property of dissolvable and removable in a period of time ranging from 0.1 to 1.0 seconds per thickness of 1 μm when formed into a film having a thickness ranging from 10 to 80 μm and water at the second temperature is supplied to the film.

7. The method of manufacturing a plurality of chips according to claim 2, wherein the protective member forming step includes forming the protective member by using polyvinyl alcohol whose saponification degree is 96 mol % or higher.

8. The method of manufacturing a plurality of chips according to claim 2, wherein the first temperature is 25° C., and the second temperature is 50° C.
